(19) United States
(12) Patent Application Publication
(10) Pub. No.: US 2013/0341703 A1
(43) Pub. Date: Dec. 26, 2013

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventors: Hiroshi SHINOHARA, Kanagawa-ken (JP); Toru Matsuda, Mie-ken (JP)

(21) Appl. No.: 13/920,321

(22) Filed: Jun. 18, 2013

(30) Foreign Application Priority Data
Jun. 20, 2012 (JP) 2012-139011

(51) Int. Cl. H01L 29/66

(52) U.S. Cl. CPC H01L 29/66833
USPC 257/326

(57) ABSTRACT

According to one embodiment, the electrode films are provided on the substrate. The first insulating films are provided between the electrode films. The second insulating film is provided on an uppermost electrode film of the electrode films. The select gate is provided on the second insulating film. The channel body extends in a stacking direction in a stacked body. The memory film is provided between the channel body and the electrode films and includes a charge storage film. The memory film includes a block film, the charge storage film, and a tunnel film. The second insulating film includes at least the block film of the memory film.

### CROSS-REFERENCE TO RELATED APPLICATION

This application is based upon and claims the benefit of priority from Japanese Patent Application No. 2012-139011, filed on Jun. 20, 2012; the entire contents of which are incorporated herein by reference.

### FIELD

Embodiments described herein relate generally to a semiconductor memory device and a method for manufacturing the same.

### BACKGROUND

A memory device of a three-dimensional structure is proposed in which a memory hole is formed in a stacked body in which an electrode film functioning as the control gate of a memory cell and an insulating film are alternately stacked in plural, and a silicon body serving as a channel is provided on the side wall of the memory hole via a charge storage film.

In such a three-dimensionally stacked memory, the electric potential of the channel body is controlled by the control of a vertical select transistor provided above the memory cell.

### BRIEF DESCRIPTION OF THE DRAWINGS

FIG. 1 is a schematic perspective view of a semiconductor memory device according to an embodiment;

FIG. 2A to FIG. 3B are schematic cross-sectional views of a part of the semiconductor memory device according to the embodiment;

FIG. 4A to FIG. 10B are schematic cross-sectional views showing a method for manufacturing the semiconductor memory device according to the embodiment; and

FIGS. 11A and 11B are schematic cross-sectional views showing a method for manufacturing the semiconductor memory device according to a comparative example.

### DETAILED DESCRIPTION

According to one embodiment, a semiconductor memory device includes a substrate, a plurality of electrode films, a plurality of first insulating films, a second insulating film, a select gate, a channel body, and a memory film. The electrode films are provided on the substrate. The first insulating films are each provided between adjacent ones of the electrode films. The second insulating film is provided on an uppermost electrode film out of the electrode films and including a film with a higher dielectric constant than silicon oxide. The select gate is provided directly on the second insulating film. The channel body extends in a stacking direction in a stacked body including the electrode films, the first insulating films, the second insulating film, and the select gate. The memory film is provided between a side wall of the channel body and each of the electrode films and includes a charge storage film. The memory film includes a block film, the charge storage film, and a tunnel film sequentially provided from a side of the electrode films. The second insulating film includes at least the block film of the memory film.

Various embodiments will be described hereinafter with reference to the accompanying drawings.

In the drawings, identical components are marked with the same reference numerals.

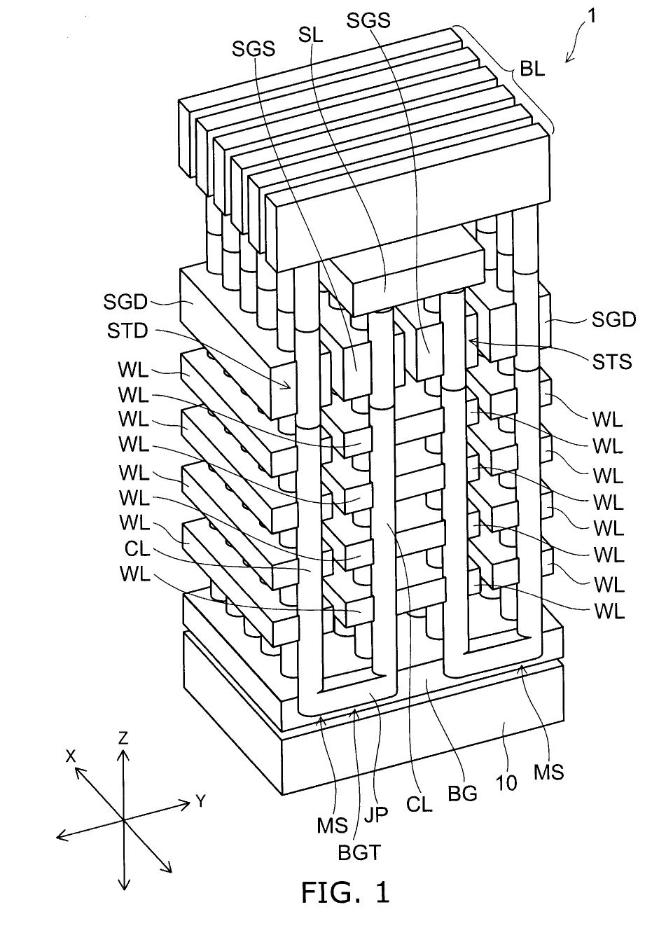

FIG. 1 is a schematic perspective view of a memory cell array 1 in a semiconductor memory device of an embodiment. In FIG. 1, the illustration of the insulating portions is omitted for easier viewing of the drawing.

In FIG. 1, an XYZ orthogonal coordinate system is introduced. Two directions parallel to the major surface of a substrate 10 and orthogonal to each other are defined as the X direction (a first direction) and the Y direction (a second direction), and the direction orthogonal to both of the X direction and the Y direction is defined as the Z direction (a third direction or the stacking direction).

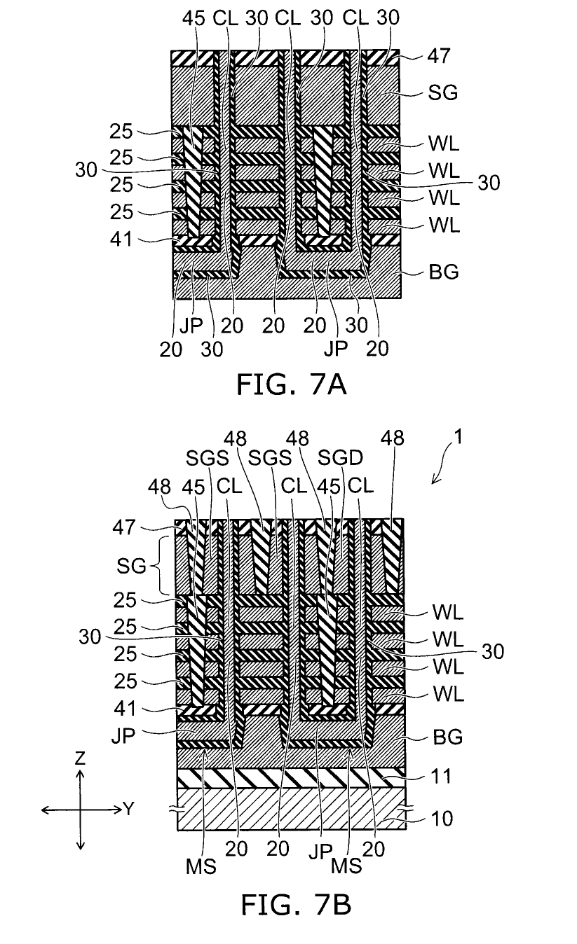

FIG. 7B is a schematic cross-sectional view of the memory cell array 1, and shows a cross section parallel to the YZ plane in FIG. 1. In FIG. 7B, the illustration of a source line SL and a bit line BL is omitted.

The memory cell array 1 includes a plurality of memory strings MS. One memory string MS is formed in a U-shaped configuration including a pair of columnar portions CL extending in the Z direction and a joining portion JP joining the lower ends of the pair of columnar portions CL.

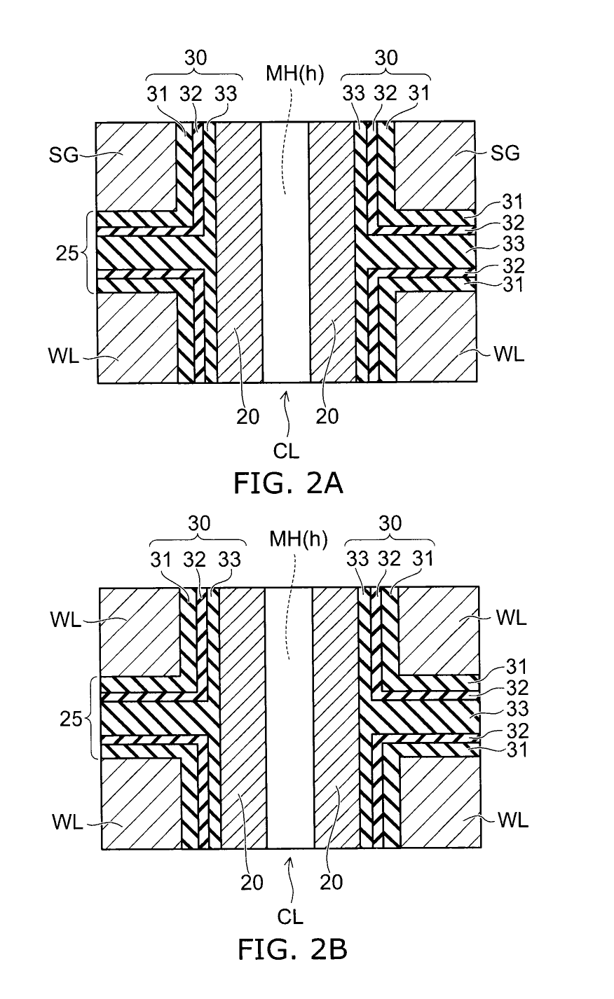

FIGS. 2A and 2B show enlarged cross-sectional views of the columnar portion CL of the memory string MS. FIG. 2A shows a cross section of a portion including an insulating film (second insulating film) 25 between the uppermost electrode film WL and a select gate SG, and FIG. 2B shows a cross section of a portion including an insulating film (first insulating film) 25 between an electrode film WL and an electrode film WL.

As shown in FIG. 7B, a back gate BG is provided on the substrate 10 via an insulating film 11. The back gate BG is a conductive film, and is, for example, a silicon film doped with an impurity.

An insulating film 41 is provided on the back gate BG. The electrode film WL and the insulating film 25 are alternately stacked in plural on the insulating film 41. Although four electrode films WL, for example, are illustrated in FIG. 1 and FIG. 7B, the number of electrode films WL is arbitrary.

The insulating film 25 is provided between upper and lower electrode films WL adjacent in the Z direction. The insulating film 25 is provided also on the uppermost electrode film WL.

The electrode film WL is a polysilicon film doped with, for example, boron as an impurity (a first silicon film), and has an electrical conductivity sufficient to function as the gate electrode of a memory cell.

The insulating film 25 includes at least part of a memory film 30, and includes a film with a higher dielectric constant than silicon oxide, as described later.

A drain-side select gate SGD is provided in the upper end portion of one of the pair of columnar portions CL of the U-shaped memory string MS, and a source-side select gate SGS is provided in the upper end portion of the other of the pair of columnar portions CL.

The drain-side select gate SGD and the source-side select gate SGS are provided on the uppermost electrode film WL via the insulating film 25. The drain-side select gate SGD and the source-side select gate SGS are provided directly on the insulating film 25 via no other film with the insulating film 25.

In the following description, the drain-side select gate SGD and the source-side select gate SGS may not be distinguished, and may be collectively referred to as a select gate SG.

The drain-side select gate SGD and the source-side select gate SGS are a polysilicon film doped with, for example, boron as an impurity similarly to the electrode film WL, and have an electrical conductivity sufficient to function as the gate electrode of a select transistor. The thickness of the drain-side select gate SGD and the thickness of the source-side select gate SGS are thicker than the thickness of each of the electrode films WL.

The drain-side select gate SGD and the source-side select gate SGS are divided in the Y direction by an insulating separation film 48. The stacked body under the drain-side select gate SGD and the stacked body under the source-side select gate SGS are divided in the Y direction by an insulating separation film 45.

A source line SL shown in FIG. 1 is provided on the source-side select gate SGS via an insulating film 47. The source line SL is, for example, a metal film. Bit lines BL that are a plurality of metal interconnections are provided on the drain-side select gate SGD and the source line SL via the insulating film 47. Each bit line BL extends in the X direction.

The memory string MS includes a channel body 20 provided in a U-shaped memory hole formed in the stacked body including the insulating film 47, the select gate SG, the plurality of insulating films 25, the plurality of electrode films WL, the insulating film 41, and the back gate BG.

The channel body 20 includes a pair of columnar portions CL extending in the Z direction in the stacked body mentioned above and a joining portion JP joining the lower ends of the pair of columnar portions CL in the back gate BG.

The channel body 20 is provided in the U-shaped memory hole via a memory film 30. The channel body 20 is, for example, a silicon film. As shown in FIGS. 2A and 2B, the memory film 30 is provided between the inner wall of the memory hole MH and the channel body 20.

Although FIGS. 2A and 2B illustrate a structure in which the channel body 20 is provided such that a hollow portion remains on the central axis side of the memory hole MH, the entire space in the memory hole MH may be filled up with the channel body 20, or a structure in which an insulating film is buried in the hollow portion on the inside of the channel body 20 is possible.

The memory film 30 includes a block film 31, a charge storage film 32, and a tunnel film 33. The block film 31, the charge storage film 32, and the tunnel film 33 are provided in this order from the electrode film WL side between each electrode film WL and the channel body 20. The block film 31 is in contact with each electrode film WL, the tunnel film 33 is in contact with the channel body 20, and the charge storage film 32 is provided between the block film 31 and the tunnel film 33.

The channel body 20 functions as a channel in a memory cell (transistor), the electrode film WL functions as the control gate of the memory cell, and the charge storage film 32 functions as a data memory layer that stores a charge injected from the channel body 20. That is, a memory cell with a structure in which the control gate surrounds the periphery of the channel is formed at the intersection between the channel body 20 and each electrode film WL.

The semiconductor memory device of the embodiment is a nonvolatile semiconductor memory device that can perform the erasing and writing of data electrically in a free manner and can retain the memory content even when the power is turned off.

The memory cell is, for example, a charge trap memory cell. The charge storage film 32 includes a large number of trap sites that trap a charge, and is a silicon nitride film, for example.

The tunnel film 33 is, for example, a silicon oxide film, and forms a potential barrier when a charge is injected from the channel body 20 into the charge storage film 32 or when the charge stored in the charge storage film 32 is diffused to the channel body 20. The tunnel film 33 is, for example, a silicon oxide film.

The block film 31 prevents the charge stored in the charge storage film 32 from diffusing to the electrode film WL. The block film 31 is, for example, a silicon nitride film or an aluminum oxide (alumina) film.

The insulating film 25 between electrode films WL and the insulating film 25 between the uppermost electrode film WL and the select gate SG are formed in the same process as the memory film 30 as described later.

Therefore, the insulating film 25 between electrode films WL and the insulating film 25 between the uppermost electrode film WL and the select gate SG include at least part of the memory film 30, and the insulating film 25 between electrode films WL and the insulating film 25 between the uppermost electrode film WL and the select gate SG have the same stacked film structure of a plurality of films.

In the example shown in FIGS. 2A and 2B, the insulating film 25 between electrode films WL includes the block film 31 provided on the electrode film WL side, the charge storage film 32 provided on the inside of the block film 31, and the tunnel film 33 provided on the inside of the charge storage film 32. Similarly, the insulating film 25 between the uppermost electrode film WL and the select gate SG includes the block film 31 provided on the uppermost electrode film WL side and on the select gate side, the charge storage film 32 provided on the inside of the block film 31, and the tunnel film 33 provided on the inside of the charge storage film 32.

The drain-side select gate SGD, the channel body 20, and the memory film 30 between them constitute a drain-side select transistor STD (shown in FIG. 1). The memory film 30 between the drain-side select gate SGD and the channel body 20 functions as the gate insulating film of the drain-side select transistor STD. Above the drain-side select gate SGD, the channel body 20 is connected to the bit line BL.

The source-side select gate SGS, the channel body 20, and the memory film 30 between them constitute a source-side select transistor STS (shown in FIG. 1). The memory film 30 between the source-side select gate SGS and the channel body 20 functions as the gate insulating film of the source-side select transistor STS. Above the source-side select gate SGS, the channel body 20 is connected to the source line SL.

The back gate BG, and the channel body 20 and the memory film 30 provided in the back gate BG constitute a back gate transistor BGT (shown in FIG. 1).

The memory cell using each electrode film WL as the control gate is provided in plural between the drain-side select transistor STD and the back gate transistor BGT. Similarly, the memory cell using each electrode film WL as the control gate is provided in plural also between the back gate transistor BGT and the source-side select transistor STS.

The plurality of memory cells, the drain-side select transistor STD, the back gate transistor BGT, and the source-side select transistor STS are connected in series via the channel body 20, and constitute one U-shaped memory string MS. The memory string MS is arranged in plural in the X direction and the Y direction; thus, a plurality of memory cells MC are provided three-dimensionally in the X direction, the Y direction, and the Z direction.

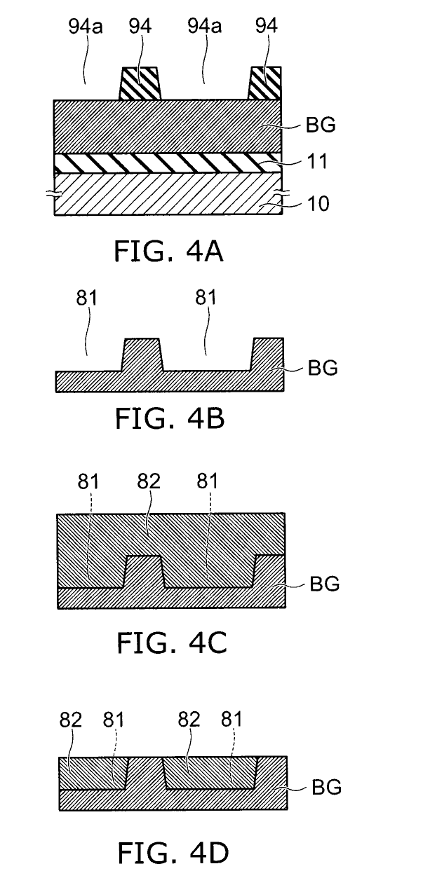

Next, a method for manufacturing a semiconductor memory device of the embodiment is described with reference to FIG. 4A to FIG. 7B.

As shown in FIG. 4A, the back gate BG is formed on the substrate 10 via the insulating film (e.g. a silicon oxide film) 11. The back gate BG is a polysilicon film doped with, for example, boron (B) as an impurity. In FIG. 4B and the subsequent drawings, the illustration of the substrate 10 and the insulating film 11 is omitted.

A resist 94 provided with openings 94a by patterning is formed on the back gate BG, and etching using the resist 94 as a mask is performed to form a plurality of trenches 81 in the back gate BG as shown in FIG. 4B.

As shown in FIG. 4C, a sacrifice film 82 is buried in the trench 81. The sacrifice film 82 is a non-doped silicon film. Here, “non-doped” means that an impurity for providing electrical conductivity is not intentionally added to the silicon film and impurities are not substantially contained other than the elements resulting from the source gas in the film-formation.

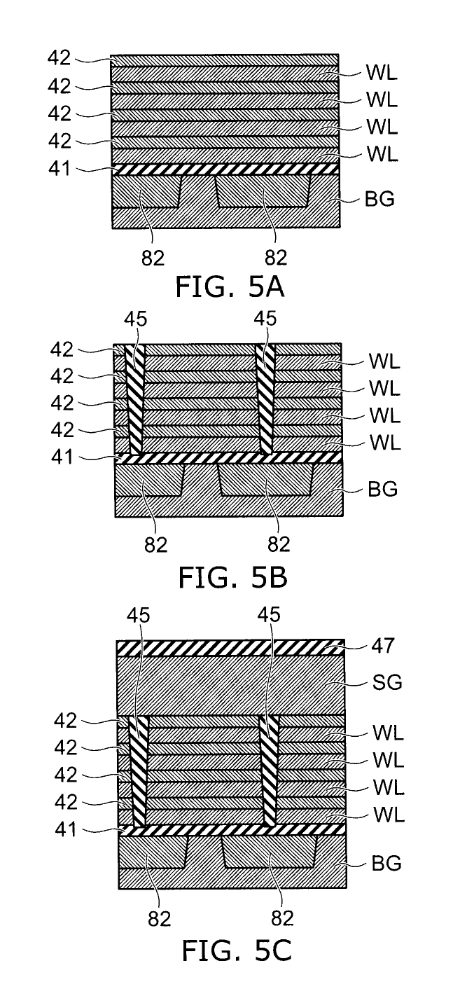

The sacrifice film 82 is etched back, and the upper surface of the protruding portion of the back gate BG between a trench 81 and a trench 81 is exposed as shown in FIG. 4D. The upper surface of the protruding portion of the back gate BG and the upper surface of the sacrifice film 82 are made flat, and the insulating film 41 is formed on the flat surface as shown in FIG. 5A. The insulating film 41 is, for example, a silicon oxide film.

The electrode film WL as the first silicon film and a non-doped silicon film 42 as a second silicon film are alternately stacked in plural on the insulating film 41. Here, “non-doped” means that an impurity for providing electrical conductivity is not intentionally added to the silicon film and impurities are not substantially contained other than the elements resulting from the source gas in the film-formation.

The non-doped silicon film 42 is finally replaced with the insulating film 25 shown in FIG. 7B in a process described later. The non-doped silicon film 42 has a film thickness sufficient to ensure the breakdown voltage between electrode films WL.

The electrode film WL is a polysilicon film doped with, for example, boron (B) as an impurity (the first silicon film). The uppermost layer in the stacked body including the plurality of electrode films WL and the plurality of non-doped silicon films 42 is the non-doped silicon film 42.

After the stacked body shown in FIG. 5A is formed, photolithography and etching are performed to form a plurality of trenches that divide the stacked body mentioned above and reach the insulating film 41. As shown in FIG. 5B, the insulating separation film 45 is buried in the trench. The insulating separation film 45 is, for example, a silicon nitride film. The insulating separation film 45 divides the stacked body including the electrode film WL and the non-doped silicon film 42 in the Y direction in FIG. 1 and FIG. 7B, on the sacrifice film 82.

Although the insulating separation film 45 is deposited also on the uppermost non-doped silicon film 42, the insulating separation film 45 on the non-doped silicon film 42 is removed and the non-doped silicon film 42 is exposed.

As shown in FIG. 5C, the select gate SG is formed on the uppermost non-doped silicon film 42, and the insulating film 47 is formed on the select gate SG. The select gate SG is a polysilicon film doped with, for example, boron (B) as an impurity. The insulating film 47 is, for example, a silicon oxide film.

The select gate SG is formed directly on the uppermost non-doped silicon film 42, and there is not a film (an insulating film such as a silicon oxide film) other than the non-doped silicon film 42 between the uppermost non-doped silicon film 42 and the select gate SG.

The back gate BG and the stacked films on the back gate BG shown in FIG. 5C are formed by, for example, the CVD (chemical vapor deposition) method.

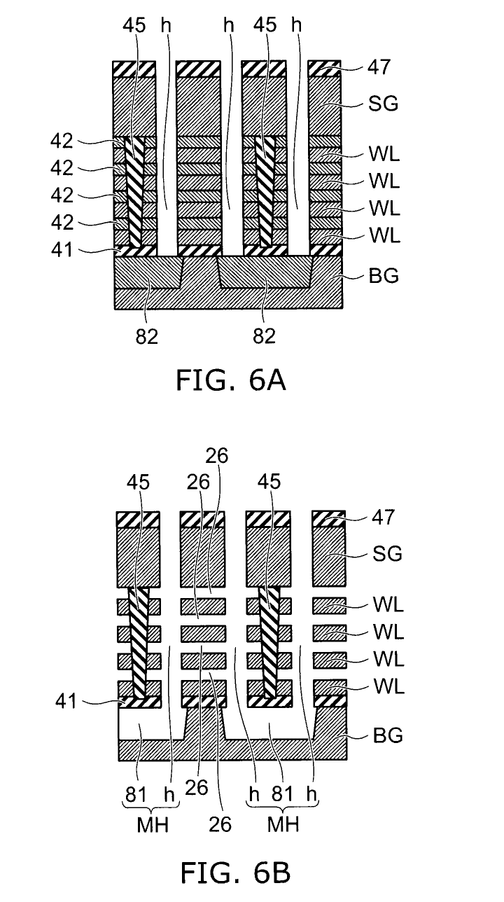

After the stacked body of FIG. 5C is formed, a plurality of holes h are formed in the stacked body as shown in FIG. 6A. The plurality of holes h are collectively formed by, for example, the RIE (reactive ion etching) method using a not-shown mask.

Since all the stacked films between the insulating film 41 and the insulating film 47 are silicon films, the setting of the conditions of RIE and the shape controllability of the hole h are easy.

The bottom of the hole h reaches the sacrifice film 82, and the sacrifice film 82 is exposed at the bottom of the hole h. A pair of holes h are formed on one sacrifice film 82, with the insulating separation film 45 located between the holes h. The insulating film 47, the select gate SG, the non-doped silicon film 42, the electrode film WL, and the insulating film 41 are exposed at the side wall of the hole h.

After the hole h is formed, the sacrifice film 82 and the non-doped silicon film 42 are removed as shown in FIG. 6B by, for example, chemical liquid treatment (wet etching) using an alkaline chemical liquid such as KOH (potassium hydroxide).

The etching rate of the silicon film to the alkaline chemical liquid depends on the concentration of the impurity doped in the silicon film. In particular, when the concentration of boron as the impurity becomes 1×10²⁰ (cm⁻³) or more, the etching rate of the silicon film decreases rapidly to become a few percent of that when the boron concentration is 1×10¹⁹ (cm⁻³) or less.

In the embodiment, the boron concentration of the back gate BG, the electrode film WL, and the select gate SG is 1×10²¹ (cm⁻³) to 2×10²¹ (cm⁻³). In the chemical liquid treatment using an alkaline chemical liquid, the etching selection ratio of the silicon film with a boron concentration of 1×10²¹ (cm⁻³) to 2×10²¹ (cm⁻³) to the non-doped silicon film is 1/1000 to 1/100.

Therefore, by the chemical liquid treatment mentioned above, the non-doped silicon film 42 and the sacrifice film 82, which is likewise a non-doped silicon film, are removed via the hole h. On the other hand, the back gate BG, the electrode film WL, and the select gate SG are left.

By the removal of the sacrifice film 82, the trench 81 appears which has been formed in the back gate BG in the process shown in FIG. 4B. As shown in FIG. 6B, a pair of holes h are connected to one trench 81. That is, the bottoms of a pair of holes h are connected to one common trench 81 to form one U-shaped memory hole MH.

By the removal of the non-doped silicon film 42, a space 26 is formed between electrode films WL and between the uppermost electrode film WL and the select gate SG. The space 26 leads to the memory hole MH.

The electrode films WL and the select gate SG are supported by the insulating separation film 45, and the state where the plurality of electrode films WL and the select gate SG are stacked via the space 26 is maintained.

After the chemical liquid treatment mentioned above, as shown in FIG. 7A, the memory film 30 is formed on the inner wall of the memory hole MH, and the insulating film 25 is formed in the space 26.

As described above with reference to FIGS. 2A and 2B, the memory film 30 includes the block film 31, the charge storage film 32, and the tunnel film 33 stacked in this order from the electrode film WL side. The insulating film 25 is formed in the space 26 shown in FIG. 6B simultaneously with the formation of the memory film 30 on the side wall of the memory hole MH. Thus, the insulating film 25 includes at least the block film 31, which is part of the memory film 30.

Depending on the height of the space 26 and the film thickness of each film included in the memory film 30, the space 26 may be filled up with only the block film 31; or a stacked film including the block film 31 and the charge storage film 32 or a stacked film including the block film 31, the charge storage film 32, and the tunnel film 33 may be buried as the insulating film 25 in the space 26.

FIGS. 2A and 2B show a structure in which a stacked film including the block film 31, the charge storage film 32, and the tunnel film 33 is buried as the insulating film 25 in the space 26.

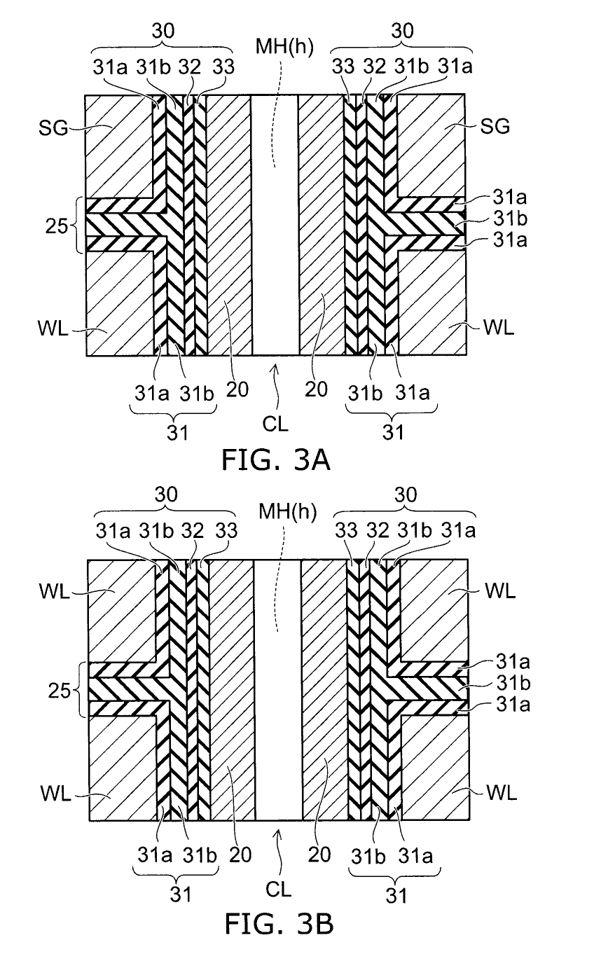

FIGS. 3A and 3B show a structure in which the space 26 is filled up with only the block film 31.

In the structure of FIGS. 3A and 3B, the block film 31 has a stacked film structure of a first block film (or a cap film) 31a and a second block film 31b.

The first block film 31a is provided on the electrode film WL side and on the select gate SG side, and the second block film 31b is provided between the first block film 31a and the charge storage film 32.

Both the first block film 31a and the second block film 31b have the function of blocking the charge stored in the charge storage film 32 from diffusing to the electrode film WL.

The second block film 31b is, for example, an aluminum oxide (alumina) film, a silicon oxide film, or a silicon oxynitride film.

For the first block film 31a, a film with a higher nitrogen concentration than the second block film 31b is used, and the first block film 31a has a higher capability of blocking the charge from diffusing to the electrode film WL than the second block film 31b. The first block film 31a is, for example, a silicon nitride film.

In both structures of FIG. 2B and FIG. 3B, the insulating film 25 between electrode films WL includes a film with a higher dielectric constant than silicon oxide (e.g. a silicon nitride film). In both structures of FIG. 2A and FIG. 3A, also the insulating film 25 between the uppermost electrode film WL and the select gate SG includes a film with a higher dielectric constant than silicon oxide (e.g. a silicon nitride film).

After the memory film 30 and the insulating film 25 are formed, the channel body 20 is formed on the inside of the memory film 30 in the memory hole MH.

After that, as shown in FIG. 7B, the select gate SG is divided into the drain-side select gate SGD and the source-side select gate SGS by the insulating separation film 48. After that, not-shown contacts, the source line SL and the bit line BL shown in FIG. 1, etc. are formed.

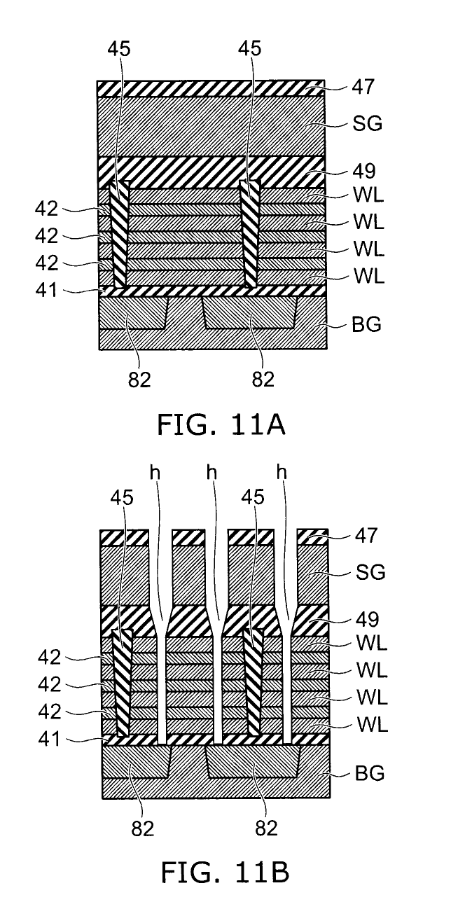

Here, FIGS. 11A and 11B show a method for manufacturing a semiconductor memory device of a comparative example.

In the comparative example, as shown in FIG. 11A, a silicon oxide film 49 is formed as an insulating film on the uppermost electrode film WL, and then the select gate SG is formed on the silicon oxide film 49.

As shown in FIG. 11B, holes h are formed in the stacked body including the insulating film 47, the select gate SG, the insulating film 49, the electrode film WL, the non-doped silicon film 42, and the insulating film 41 by the RIE method.

In the comparative example, when the hole h is formed, a stacked body in which the silicon oxide film 49 different from a silicon film exists in a middle position of the stacked silicon films is processed. Hence, the side wall of the hole h in the portion piercing the silicon oxide film 49 is formed in a tapered shape inclined with respect to the substrate surface, and the diameter of the hole h provided in the silicon oxide film 49 is likely to be smaller on the lower end side than on the upper end side.

Thus, the diameter of the hole h is not equalized between the upper side and the lower side of the silicon oxide film 49, and consequently a variation in the characteristics of the memory string may be caused.

In contrast, in the embodiment, when the hole h is formed in the process shown in FIG. 6A, there is not an insulating film different from a silicon film between the uppermost electrode film WL and the select gate SG. In the embodiment, silicon films are processed from the select gate SG to the lowermost electrode film WL. Therefore, the setting of the conditions of RIE and the shape controllability of the hole h are easy, and a hole h with a uniform diameter can be formed from the select gate SG to the lowermost electrode film WL. Thus, the diameter of the columnar portion CL of the memory string can be made uniform from the select transistor to the lowermost memory cell, and desired characteristics can be obtained.

In the comparative example, since the insulating film between the uppermost electrode film WL and the select gate SG is a single-layer film of the silicon oxide film 49, the film thickness of the silicon oxide film 49 sufficient to ensure the breakdown voltage between the electrode film WL and the select gate SG tends to be increased. An increase in the thickness of the insulating film between the uppermost electrode film WL and the select gate SG causes an increase in the parasitic resistance of the channel due to the increase of the distance between the channels of the select transistor and the uppermost memory cell.

On the other hand, in the embodiment, the insulating film 25 between the select gate SG and the uppermost electrode film WL includes at least part of the memory film 30 as described above, and includes a film with a higher dielectric constant than silicon oxide (e.g. a silicon nitride film). Therefore, the breakdown voltage of the insulating film 25 of the embodiment is higher than that of a single-layer film of a silicon oxide film, and the insulating film 25 of the embodiment can be made thinner than the single-layer film of a silicon oxide film.

Thus, the distance between the channels of the select transistor and the uppermost memory cell can be made shorter than in the case of the comparative example, and the parasitic resistance of the channel can be reduced.

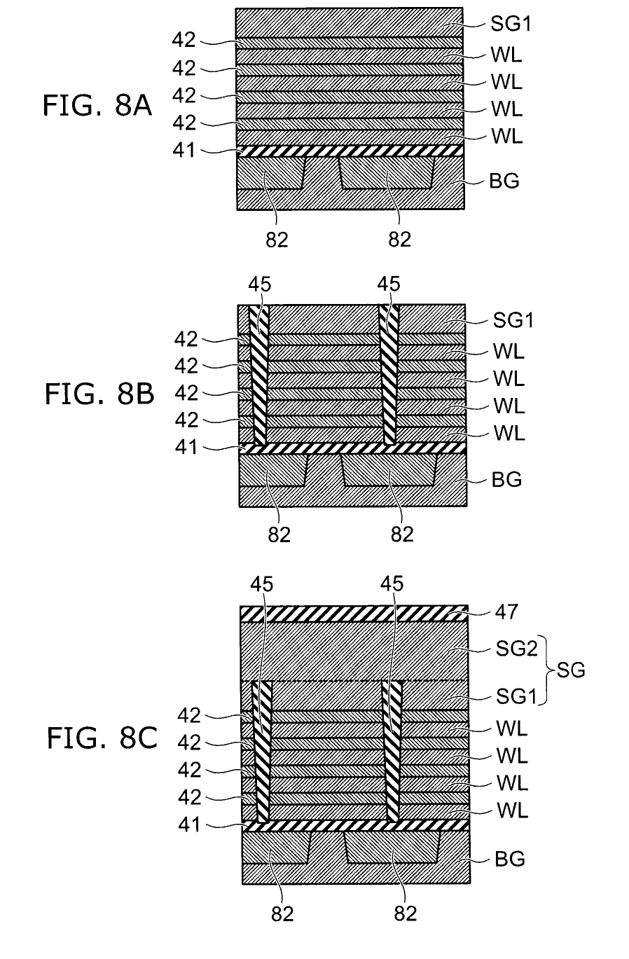

Next, FIG. 8A to FIG. 10B are schematic cross-sectional views showing another method for manufacturing a semiconductor memory device of the embodiment.

Similarly to the embodiment described above, after trenches are formed in the back gate BG and the sacrifice film 82 is buried in the trench, as shown in FIG. 8A, the electrode film WL and the non-doped silicon film 42 are alternately stacked in plural on the back gate BG via the insulating film 41.

In this embodiment, the select gate SG is stacked by two separate steps. First, a first-story select gate SG1 is formed on the uppermost non-doped silicon film 42 as shown in FIG. 8A. The select gate SG1 is a silicon film doped with, for example, boron as an impurity.

Next, the stacked body including the select gate SG1, the plurality of non-doped silicon films 42, the plurality of electrode films WL, and the insulating film 41 is divided by the insulating separation film 45 as shown in FIG. 8B.

After that, as shown in FIG. 8C, a second-story select gate SG2 is formed on the first-story select gate SG1. The second-story select gate SG2 is the same material as the first-story select gate SG1, and is a silicon film doped with boron as an impurity.

That is, in this embodiment, the select gate SG is formed of the select gate SG1 and the select gate SG2 formed by two separate processes via the process of forming the insulating separation film 45.

Also in this embodiment, the select gate SG is formed on the uppermost electrode film WL via the non-doped silicon 42, and the select gate SG is formed directly on the uppermost non-doped silicon film 42. There is not an insulating film such as a silicon oxide film different from a silicon film between the uppermost non-doped silicon film 42 and the select gate SG.

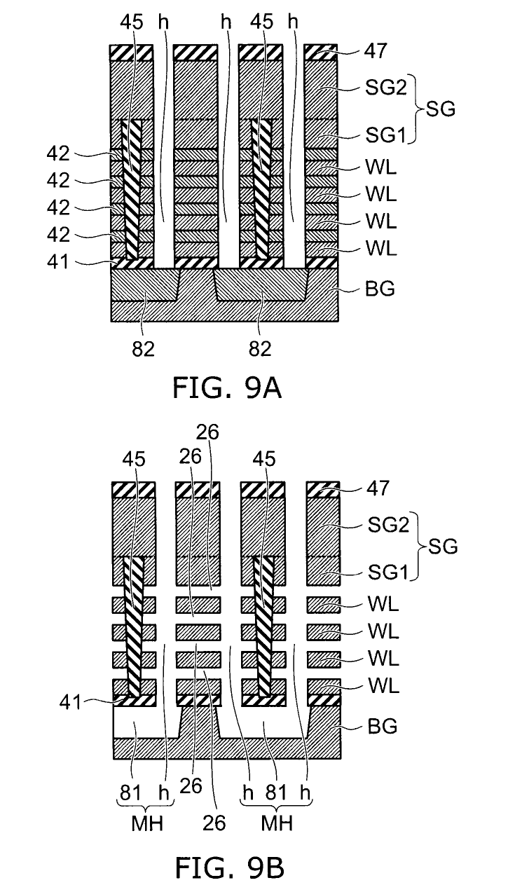

The insulating film 47 is formed on the second-story select gate SG2. As shown in FIG. 9A, holes h are formed in the stacked body including the insulating film 47, the select gate SG, the plurality of non-doped silicon films 42, the plurality of electrode films WL, and the insulating film 41 by the RIE method.

Also in the embodiment, silicon films are processed from the select gate SG to the lowermost electrode film WL. Therefore, the setting of the conditions of RIE and the shape controllability of the hole h are easy, and a hole h with a uniform diameter can be formed from the select gate SG to the lowermost electrode film WL. Thus, the diameter of the columnar portion CL of the memory string can be made uniform from the select transistor to the lowermost memory cell, and desired characteristics can be obtained.

After the hole h is formed, similarly to the embodiment described above, the non-doped silicon film 42 and the sacrifice film 82 are removed via the hole h as shown in FIG. 9B by treatment using an alkaline chemical liquid.

The electrode films WL and the select gate SG are supported by the insulating separation film 45, and the state where the plurality of electrode films WL and the select gate SG are stacked via the space 26 is maintained. In the embodiment, since the upper portion of the insulating separation film 45 cuts into the lower portion of the select gate SG (the select gate SG1), the support of the select gate SG by the insulating separation film 45 is stabilized.

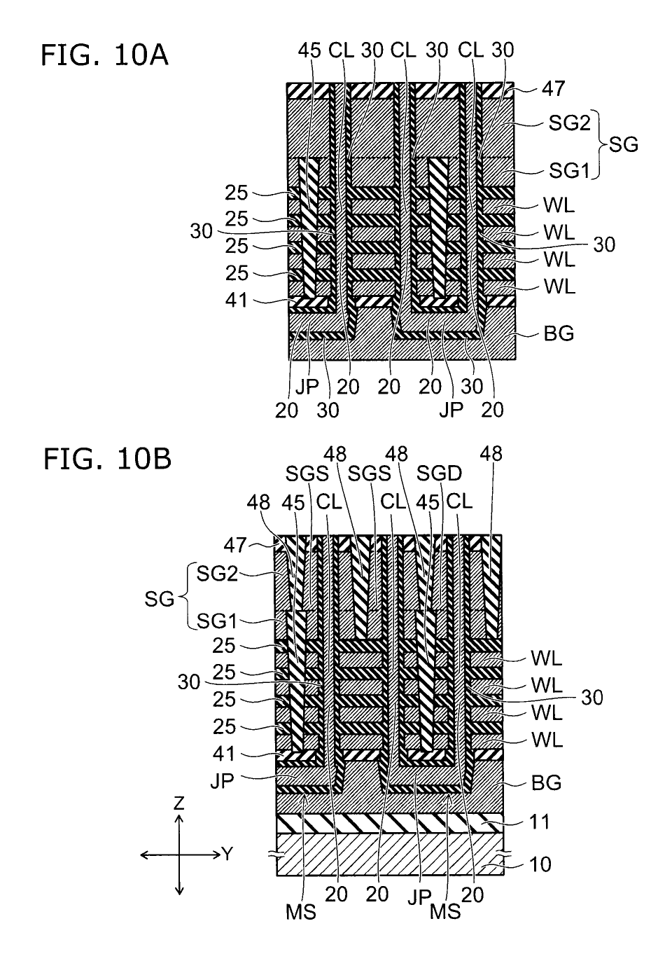

After the memory hole MH and the space 26 are formed, as shown in FIG. 10A, the memory film 30 is formed on the inner wall of the memory hole MH; the insulating film 25 is formed in the space 26 between conductive films WL and in the space 26 between the uppermost electrode film WL and the select gate SG; and the channel body 20 is formed on the inner side of the memory film 30 in the memory hole MH.

Also in the embodiment, the insulating film 25 is formed in the space 26 shown in FIG. 9B simultaneously with the formation of the memory film 30 on the side wall of the memory hole MH. Therefore, the insulating film 25 between the select gate SG and the uppermost electrode film WL includes at least part of the memory film 30 as shown in FIG. 2A or FIG. 3A, and includes a film with a higher dielectric constant than silicon oxide (e.g. a silicon nitride film). Thus, the breakdown voltage of the insulating film 25 of the embodiment is higher than that of the single-layer film of a silicon oxide film of the comparative example mentioned above, and the insulating film 25 of the embodiment can be made thinner than the single-layer film of a silicon oxide film.

Therefore, also in the embodiment, the distance between the channels of the select transistor and the uppermost memory cell can be made shorter than in the case of the comparative example, and the parasitic resistance of the channel can be reduced.

After that, as shown in FIG. 10B, the select gate SG is divided into the drain-side select gate SGD and the source-side select gate SGS by the insulating separation film 48.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a substrate;
a plurality of electrode films provided on the substrate;
a plurality of first insulating films each provided between adjacent ones of the electrode films;
a second insulating film provided on an uppermost electrode film of the electrode films and including a film with a higher dielectric constant than silicon oxide;
a select gate provided directly on the second insulating film;
a channel body extending in a stacking direction in a stacked body including the electrode films, the first insulating films, the second insulating film, and the select gate; and
a memory film provided between a side wall of the channel body and each of the electrode films, the memory film including a charge storage film,
the memory film including a block film, the charge storage film, and a tunnel film sequentially provided from a side of the electrode films,
the second insulating film including at least the block film of the memory film.

2. The device according to claim 1, wherein the first insulating film and the second insulating film have a same stacked film structure of a plurality of films.

3. The device according to claim 1, wherein the second insulating film includes a silicon nitride film.

4. The device according to claim 1, wherein the second insulating film includes an aluminum oxide film.

5. The device according to claim 1, wherein the block film includes
a first block film provided on a side of the electrode film, and
a second block film provided between the first block film and the charge storage film,
the first block film has a nitrogen concentration higher than a nitrogen concentration of the second block film.

6. The device according to claim 5, wherein
the first block film is a silicon nitride film and
the second block film is one of an aluminum oxide film, a silicon oxide film, and a silicon oxynitride film.

7. The device according to claim 1, wherein the electrode film is a silicon film doped with an impurity.

8. A semiconductor memory device comprising:
a substrate;
a plurality of electrode films provided on the substrate;
a plurality of first insulating films each provided between adjacent ones of the electrode films;
a second insulating film provided on an uppermost electrode film of the electrode films and including a film with a higher dielectric constant than silicon oxide;
a select gate provided directly on the second insulating film;
a channel body extending in a stacking direction in a stacked body including the electrode films, the first insulating films, the second insulating film, and the select gate; and
a memory film provided between a side wall of the channel body and each of the electrode films, the memory film including a charge storage film,
the first insulating film and the second insulating film having a same stacked film structure of a plurality of films.

9. The device according to claim 8, wherein the second insulating film includes a silicon nitride film.

10. The device according to claim 8, wherein the second insulating film includes an aluminum oxide film.

11. The device according to claim 8, wherein the memory film includes a block film, the charge storage film, and a tunnel film sequentially provided from a side of the electrode films.

12. The device according to claim 11, wherein the block film includes:
a first block film provided on the electrode film side; and
a second block film provided between the first block film and the charge storage film,
the first block film has a nitrogen concentration higher than a nitrogen concentration of the second block film.

13. The device according to claim 12, wherein
the first block film is a silicon nitride film and
the second block film is one of an aluminum oxide film, a silicon oxide film, and a silicon oxynitride film.

14. The device according to claim 8, wherein the electrode film is a silicon film doped with an impurity.

15. A method for manufacturing a semiconductor memory device comprising:
forming a stacked body on a substrate, the stacked body including a plurality of first silicon films containing an impurity, a plurality of non-doped second silicon films provided between adjacent ones of the first silicon films and on the uppermost first silicon film, and a select gate formed of a silicon film containing an impurity and provided directly on the uppermost second silicon film;
forming a hole piercing the stacked body;
performing etching via the hole to remove the second silicon film to form a space between adjacent ones of the first silicon films and between the uppermost first silicon film and the select gate;
forming a memory film including a charge storage film on a side wall of the hole and forming an insulating film including at least part of the memory film in the space; and
forming a channel body on an inside of the memory film in the hole.

16. The method according to claim 15, wherein
the forming the select gate includes forming a first-story select gate on the uppermost second silicon film and forming a second-story select gate on the first-story select gate,
an insulating separation film that divides the first-story select gate, the second silicon films, and the first silicon films into a plurality of pieces is formed after the first-story select gate is formed, and
the second-story select gate is formed on the first-story select gate after the insulating separation film is formed.

17. The method according to claim 16, wherein an upper portion of the insulating separation film cuts into a lower portion of the select gate.

18. The method according to claim 15, wherein the first silicon film and the select gate contain boron as the impurity.

19. The method according to claim 15, wherein the hole is formed by etching the stacked body by an RIE (reactive ion etching) method in a state where there is not an insulating film different from a silicon film between the uppermost second silicon film and the select gate.

20. The method according to claim 15, wherein the second silicon film is removed using an alkaline chemical solution.
